(19) United States
(12) Patent Application Publication
(10) Pub. No.: US 2007/0148927 A1
(43) Pub. Date: Jun. 28, 2007

(54) ISOLATION STRUCTURE OF SEMICONDUCTOR DEVICE AND METHOD FOR FORMING THE SAME

(76) Inventor: Dae Young Kim, Chungcheongnam-do (KR)

Correspondence Address: SHERR & NOURSE, PLLC, 620 HERNDON PARKWAY, SUITE 200, HERNDON, VA, 20170, US

(21) Appl. No.: 11/563,407

(22) Filed: Nov. 27, 2006

(30) Foreign Application Priority Data
Dec. 28, 2005 (KR) 10-2005-0132704

(51) Int. Cl. H01L 21/04

(52) U.S. Cl. 438/510

(57) ABSTRACT

Embodiments of an isolation structure and method of forming the same are disclosed, and may include a shallow trench isolation region formed on a semiconductor substrate, and an isolation layer that may include a first oxide layer, a plurality of silicon nitride layers and silicon oxide layers, and a second oxide layer. The first oxide layer may be formed in the shallow trench isolation region by a rapid thermal treatment, the plurality of silicon nitride layers and silicon oxide layers may be laminated on the first oxide layer, and the second oxide layer may be formed on the plurality of silicon nitride layers and silicon oxide layers by a high density plasma process to fill gaps.

The present application claims priority under 35 U.S.C. 119 and 35 U.S.C. 365 to Korean Patent Application No. 10-2005-0132704 (filed on Dec. 28, 2005), which is hereby incorporated by reference in its entirety.

### BACKGROUND

Embodiments relate to an isolation structure of a semiconductor device and a method for forming the same.

As a need for faster semiconductor devices has increased, some focus has been placed on research regarding transistor mobility.

Carrier mobility may relate to stress occurring around a channel of a transistor. Stress reduction of a shallow trench isolation (“STI”) may therefore be significant.

For example, after a formation of an STI Tetra Ethyl Ortho Silicate (“TEOS”) may be used to fill a gap of the STI. In this respect, compressive stress may occur around the STI region.

The compressive stress that may occurs could have a detrimental effect on the mobility and leakage current of a transistor, based on a distance between the STI and the transistor.

To reduce the above described stress, a plasma nitrification processing method has sometimes been used. Such a process, however, may have certain drawbacks. For example, it may be difficult to reduce stress around an STI region an affect a short channel, for example of less than 90 nm, when only a small amount of nitrogen N-doping is used.

### SUMMARY

Accordingly, embodiments are directed to an isolation structure of a semiconductor device and a method for forming the same that may substantially obviate one or more problems.

Embodiments may provide an isolation structure of a semiconductor device, and a method for forming the same, which may reduce stress of an isolation layer in a shallow trench isolation region.

Additional advantages, objects, and features of embodiments may be set forth in part in the description which follows and in part will become apparent to those having ordinary skill in the art upon examination of the following or may be learned from practice of embodiments. Objectives and other advantages of embodiments may be realized and attained by the structure particularly pointed out in the written description and claims hereof, as well as the appended drawings.

In embodiments, an isolation structure of a semiconductor device may include a shallow trench isolation region formed in a semiconductor substrate, and an isolation layer formed in the shallow trench isolation region and including a nitride layer and an oxide layer.

In embodiments, an isolation structure of a semiconductor device may include a shallow trench isolation region formed on a semiconductor substrate, and an isolation layer including a first oxide layer, a plurality of silicon nitride layers and silicon oxide layers, and a second oxide layer, wherein the first oxide layer may be formed in the shallow trench isolation region by a rapid thermal treatment, the plurality of silicon nitride layers and silicon oxide layers may be laminated on the first oxide layer, and the second oxide layer may be formed on the plurality of silicon nitride layers and silicon oxide layers to fill gaps by a high density plasma process.

In embodiments, a method for forming an isolation structure of a semiconductor device may include forming a shallow trench isolation region in a semiconductor substrate, and forming an isolation layer having a nitride layer and an oxide layer formed in the shallow trench isolation region.

### BRIEF DESCRIPTION OF THE DRAWINGS

FIG. 1 is an example cross-sectional illustration of an isolation structure of the semiconductor device according to embodiments; and

FIGS. 2A through 2E are example cross-sectional illustrations of a semiconductor device, to illustrate a method for forming a device, according to embodiments.

### DETAILED DESCRIPTION

Hereinafter, embodiments of an isolation structure of a semiconductor device and a method for forming the same will be described with reference to the accompanying drawings.

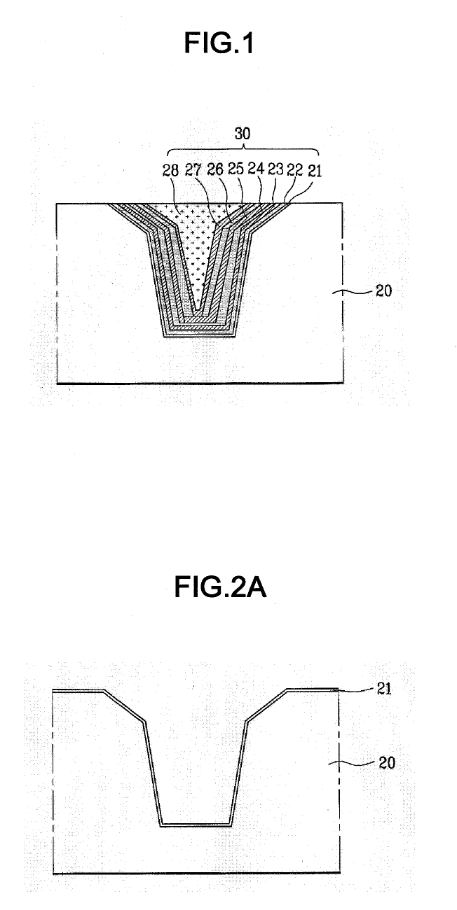

FIG. 1 is an example cross-sectional illustration of an isolation structure of a semiconductor device according to embodiments.

Referring to FIG. 1, in an isolation structure of a semiconductor device, a shallow trench isolation (STI) region may be formed in one region of semiconductor substrate 20. In embodiments, isolation layer 30 may be formed in a shallow trench isolation region. Isolation layer 30 may be composed of multiple insulating layers, formed such that nitride layers and oxide layers may be alternately deposited to form an Oxide Nitride Oxide (ONO) structure therein.

The insulating layers making up isolation layer 30 may include first, second, third, fourth, fifth, sixth, seventh, and eighth insulating layers 21, 22, 23, 24, 25, 26, 27, and 28, respectively.

In embodiments, first, third, fifth, seventh, and eighth insulating layers 21, 23, 25, 27, and 28 may each be formed of a silicon oxide layer. Second, fourth, and sixth insulating layers 22, 24, and 26 may each be formed of a silicon nitride layer SiN.

In embodiments, first insulating layer 21 may be an oxide layer formed by a rapid thermal anneal (RTA). Second, fourth, and sixth insulating layers 22, 24, and 26 may be silicon nitride layers, which may have a thickness of approximately 20 Å.

Third, fifth, and seventh insulating layers 23, 25, and 27 may be silicon nitride layers, which may have a thickness of approximately 20 Å. Eighth insulating layer 28 may be formed on or above a gap of the STI region, for example by a high-density plasma process, according to embodiments.

Isolation layer 30 may be formed in the STI region by alternately depositing nitride layers and oxide layers in a multilayer fashion. In embodiments, a plurality of insulating layers made of silicon nitride layer SiN may be included in isolation layer 30, thereby reducing stress. In embodiments, the insulating layers may alternate between silicon nitride and oxide layers.

In embodiments, the silicon nitride layer/silicon oxide layer may be formed alternately and repeatedly three times. However, the silicon nitride layer/silicon oxide layer may be repeatedly deposited more than three times according to a width and a depth of the STI region. In embodiments, the silicon nitride layer/silicon oxide layer may be repeatedly deposited fewer than three times.

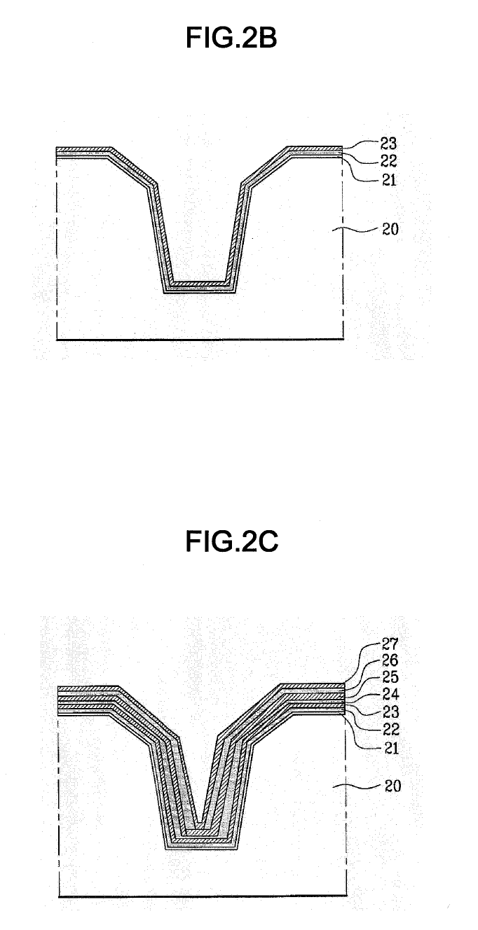

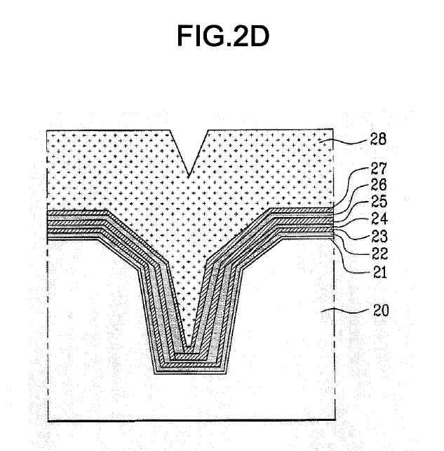

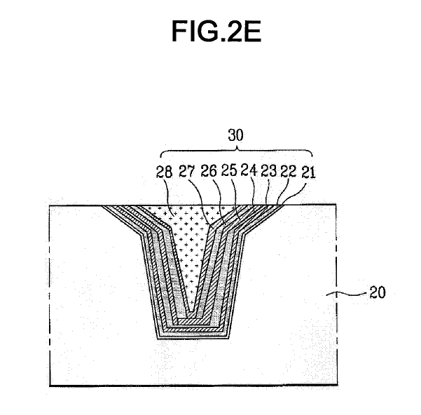

FIGS. 2A through 2E are example cross-sectional illustrations of a semiconductor device, to illustrate a method for forming a device, according to embodiments.

Referring to FIG. 2A, an STI region may be formed at one region of semiconductor substrate 20, for example by a photolithography etch process.

Next, an RTA may be provided over an entire surface of semiconductor substrate 20, including over a shallow trench isolation region. First insulating layer 21 may thus be formed. In embodiments, first insulating layer 21 may be an oxide layer.

Referring to FIG. 2B, second and third insulating layers 22 and 23 may be sequentially formed by a chemical vapor deposition method. Second insulating layer 22 may be formed by depositing a silicon nitride layer SiN, for example having a thickness of 20 Å. Third insulating layer 23 may be formed by depositing a silicon oxide layer SiO₂ having, for example, a thickness of 20 Å.

Referring to FIG. 2C, fourth and fifth insulating layers 24, 25 and sixth and seventh insulating layers 26, 27 may be sequentially formed, for example by a chemical vapor deposition method, to form multiple layers. Fourth and sixth insulating layers 24 and 26 may be formed by depositing a silicon nitride layer SiN having a thickness of 20 Å. Fifth and seventh insulating layers 25 and 25 may be formed by depositing a silicon oxide layer SiO₂ having a thickness of 20 Å.

Formation of the silicon nitride layer SiN may be performed at a temperature ranging from approximately 680 to 720 C degrees, at a pressure ranging from approximately 0.42 to 0.44 torr, and for a time duration of approximately 1 to 2 minutes. The silicon nitride layer SiN may be formed by implanting SiH₂Cl₂ of approximately 70˜90 slm, NH₃ of approximately 0.8˜1.0 slm, and N₂ of approximately 0.4˜0.6 slm.

Formation of the silicon oxide layer SiO₂ may be performed at a temperature ranging from approximately 780 to 800 C degrees, at a pressure ranging from approximately 0.44 to 0.46 torr, and for a time duration of approximately 4 to 6 minutes. The silicon oxide layer SiO₂ may be formed by implanting SiH₂Cl₂ of approximately 25˜35 slm, N₂O of approximately 50˜60 slm, and N₂ of approximately 50 slm in the shallow trench isolation region.

Although in embodiments the silicon nitride layers/silicon oxide layers may be repeatedly and alternately formed three times, they may also be formed more than three times, for example according to a width and a depth of the shallow trench isolation region.

Referring to FIG. 2D, eighth insulating layer 28 may be formed on seventh insulating layer 27 to fill the STI region, for example using a high-density plasma method. Eighth insulating layer 28 may be formed of an oxide layer, according to embodiments.

Referring to FIG. 2E, first to eighth insulating layers 21 through 28 may be densified. A chemical mechanical polishing (CMP) process may then be performed to remove first to eighth insulating layers 21 through 28 to form isolation layer 30, so that they remain only in the shallow trench isolation region. The densification process may be performed at a temperature ranging from approximately 1125 to 1175 C degrees and at a pressure of approximately 760 torr for a time duration of approximately 7 to 9 minutes. This may occur prior to the chemical mechanical polishing process. In embodiments, N₂ of approximately 0.5 slm may be implanted.

According to embodiments, isolation layer 30 may be formed at the STI region to have a plurality of Oxide Nitride Oxide (ONO) structures. That is, a plurality of insulating layers formed of silicon nitride layer SiN may be formed in isolation layer 30 of the STI region. This may reduce the occurrence of stress.

For example, an isolation layer may have a plurality of Oxide Nitride Oxide (ONO) structures, formed by alternately and repeatedly inserting nitride layer/oxide layer in the STI region. Embodiments may include insulating layers formed of silicon nitride layers SiN in the isolation layer. According to embodiments, an isolation structure of a semiconductor device and a method for forming the same may have various advantages, including a reduction of stress.

It will be apparent to those skilled in the art that various modifications and variations can be made to embodiments. Thus, it is intended that embodiments cover modifications and variations thereof within the scope of the appended claims. It is also understood that when a layer is referred to as being “on” another layer or substrate, it can be directly on the other layer or substrate, or intervening layers may also be present.

What is claimed is:

1. A device comprising:
a shallow trench isolation region formed in a semiconductor substrate; and
an isolation layer formed above the shallow trench isolation region, the isolation layer comprising at least one nitride layer and at least one oxide layer.

2. The device of claim 1, wherein the at least one nitride layer comprises a plurality of nitride layers, and the at least one oxide layer comprise a plurality of oxide layers, and wherein the plurality of nitride layers and oxide layers are alternately deposited to form alternating nitride and oxide layers.

3. The device of claim 1, wherein the at least one nitride layer comprises a silicon nitride layer.

4. The device of claim 1, wherein the at least one oxide layer comprises a silicon oxide layer.

5. A device comprising:
a shallow trench isolation region formed on a semiconductor substrate; and
an isolation layer having a first oxide layer, a plurality of silicon nitride layers and silicon oxide layers, and a second oxide layer, wherein the first oxide layer is formed above the shallow trench isolation region by a rapid thermal treatment, the plurality of silicon nitride layers and silicon oxide layers are laminated on the first oxide layer, and the second oxide layer is formed above the plurality of silicon nitride layers and silicon oxide layers by a high density plasma process.

6. The device of claim 5, wherein the second oxide layer is formed above the plurality of silicon nitride layers and silicon oxide layers to fill gaps.

7. The device of claim 5, wherein the plurality of silicon nitride layers and the silicon oxide layers are alternately formed to comprise alternating layers of silicon nitride and silicon oxide.

8. A method, comprising:
forming a shallow trench isolation region in a semiconductor substrate; and
forming an isolation layer having a nitride layer and an oxide layer formed in the shallow trench isolation region.

9. The method of claim 8, further comprising forming a plurality of nitride layers and a plurality of oxide layers in the shallow trench isolation region, wherein each of the plurality of nitride layers and oxide layers are alternately formed to comprise alternating nitride and oxide layers.

10. The method of claim 8, wherein the nitride layer comprises a silicon nitride layer.

11. The method of claim 8, wherein the oxide layer comprises a silicon oxide layer.

12. The method of claim 8, wherein forming the isolation layer comprises:
forming the nitride layer and the oxide layer above the semiconductor substrate, including filling the shallow trench isolation region with the nitride layer and the oxide layer; and
performing a chemical mechanical polishing process to remove at least a portion of the nitride layer and the oxide layer so that the nitride layer and the oxide layer remain only in the shallow trench isolation region.

13. The method of claim 12, wherein prior to the chemical mechanical polishing process a densification process is performed at a temperature in a range of 1125 to 1175 C degrees and at a pressure of approximately 760 torr for a time duration of approximately 7 to 9 minutes.

14. The method of claim 13, wherein the densification process is performed by implanting N₂ of approximately 0.5 slm.

15. The method of claim 8, wherein forming the isolation layer comprises:
performing a rapid thermal anneal process to form a first oxide layer in the shallow trench isolation region;
alternately forming a plurality of nitride layers and second oxide layers above the first oxide layer; and
forming a third oxide layer above the plurality of nitride layers and second oxide layers by a high-density plasma process.

16. The method of claim 15, wherein the third oxide layer is formed to fill gaps.

17. The method of claim 8, wherein the nitride layer is formed at a temperature in a range of 680 to 720 C degrees, at a pressure in a range of 0.42 to 0.44 torr, and for a time duration of approximately 1 to 2 minutes.

18. The method of claim 17, wherein the nitride layer is formed by implanting SiH₂Cl₂ of 70˜90 slm, NH₃ of 0.8˜1.0 slm, and N₂ of 0.4˜0.6 slm in the shallow trench isolation region.

19. The method of claim 8, wherein the oxide layer is formed at a temperature in a range of 780 to 800 C degrees, at a pressure in a range of 0.44 to 0.46 torr, and for a time duration of 4 to 6 minutes.

20. The method of claim 19, wherein the oxide layer is formed by implanting SiH₂Cl₂ of 25˜35 slm, N₂O of 50˜60 slm, and N₂ of 50 slm in the shallow trench isolation region.
